(19) United States
(12) Patent Application Publication
(10) Pub. No.: US 2025/0120071 A1
(43) Pub. Date: Apr. 10, 2025

(54) SEMICONDUCTOR DEVICE INCLUDING TRANSISTOR AND METHOD FOR FABRICATING THE SAME

(71) Applicant: SK hynix Inc., Gyeonggi-do (KR)

(72) Inventor: Jun Sik KIM, Gyeonggi-do (KR)

(21) Appl. No.: 18/586,577

(22) Filed: Feb. 26, 2024

(30) Foreign Application Priority Data
Oct. 6, 2023 (KR) 10-2023-0133104

(51) Int. Cl. H10B 12/00

(52) U.S. Cl. CPC H10B 12/488; H10B 12/482; H10B 12/485

(57) ABSTRACT

A semiconductor device includes a plurality of semiconductor pillars having first and second sides facing each other in a first direction, and arranged in a second direction crossing the first direction; a plurality of insulating pillars having first and second sides facing each other in the first direction, and arranged alternately with the semiconductor pillars in the second direction; a back gate line formed on the first sides of the semiconductor pillars and the first sides of the insulating pillars, and extending in the second direction; and a front gate line formed on the second sides of the semiconductor pillars and the second sides of the insulating pillars, and extending in the second direction, wherein the semiconductor pillars respectively include protrusion portions that protrude more than the insulating pillars toward the front gate line in the first direction, and the front gate line surrounds a side of the protrusion portion.

### CROSS-REFERENCE TO RELATED APPLICATIONS

The present application claims priority under 35 U.S.C 119(a) to Korean Patent Application No. 10-2023-0133104, filed on Oct. 6, 2023, which is incorporated herein by reference in its entirety.

### BACKGROUND

### 1. Field

Various embodiments of the present disclosure relate generally to a semiconductor device, and more particularly, to a semiconductor device including a transistor, and a method for fabricating the semiconductor device.

### 2. Description of the Related Art

The development of the electronics industry requires electronic products to gradually become smaller, more highly integrated and have high-performance, while the operation rate of the electronic products is required to increase.

In order to satisfy these demands, it is required to develop technology that may maintain and/or improve the characteristics of a unit element that constitutes an electronic product, such as a transistor, while reducing the size of the unit element.

### SUMMARY

Embodiments of the present disclosure are directed to a semiconductor device including a transistor capable of increasing integration degree and improving operation characteristics. Embodiments of the present disclosure are also directed to a method for fabricating the semiconductor device.

In accordance with an embodiment of the present disclosure, a semiconductor device includes: a plurality of semiconductor pillars having first and second sides facing each other in a first direction, and arranged in a second direction intersecting with the first direction; a plurality of insulating pillars having first and second sides facing each other in the first direction, and arranged alternately with the semiconductor pillars in the second direction; a back gate line formed on the first sides of the semiconductor pillars and the first sides of the insulating pillars, and extending in the second direction; and a front gate line formed on the second sides of the semiconductor pillars and the second sides of the insulating pillars, and extending in the second direction, wherein the semiconductor pillars respectively include protrusion portions that protrude more than the insulating pillars toward the front gate line in the first direction, and the front gate line surrounds a side of the protrusion portion.

In accordance with another embodiment of the present disclosure, a semiconductor device includes: a back gate line having both sides facing each other in a first direction and extending in a second direction intersecting with the first direction; two line patterns respectively formed on the both sides of the back gate line and respectively having first sides facing the back gate line, each of the two line patterns including a plurality of semiconductor pillars and a plurality of insulating pillars that are alternately arranged in the second direction; and two front gate lines respectively formed on two second sides facing the first sides of the two line patterns in the first direction.

In accordance with another embodiment of the present disclosure, a method for fabricating a semiconductor device includes: forming an initial line pattern including a plurality of initial semiconductor pillars and a plurality of initial insulating pillars that are arranged in a second direction intersecting with a first direction; forming a back gate line between the initial line pattern and another initial line pattern adjacent to the initial line pattern; forming line patterns including a plurality of semiconductor pillars and a plurality of insulating pillars that are arranged in the second direction by dividing the initial line pattern into two parts in the first direction; and forming front gate lines on facing sides of the line patterns, respectively.

### BRIEF DESCRIPTION OF THE DRAWINGS

FIGS. 1A to 10 illustrate a semiconductor device and a method for fabricating the same in accordance with an embodiment of the present disclosure.

FIGS. 11 to 14 are cross-sectional views illustrating a semiconductor device and a method for fabricating the same in accordance with another embodiment of the present disclosure.

### DETAILED DESCRIPTION

Various embodiments of the present disclosure will be described below in more detail with reference to the accompanying drawings. the embodiments of the present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

Hereinafter, the various embodiments of the present disclosure will be described in detail with reference to the attached drawings.

The drawings are not necessarily to scale and in some instances, proportions may have been exaggerated to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

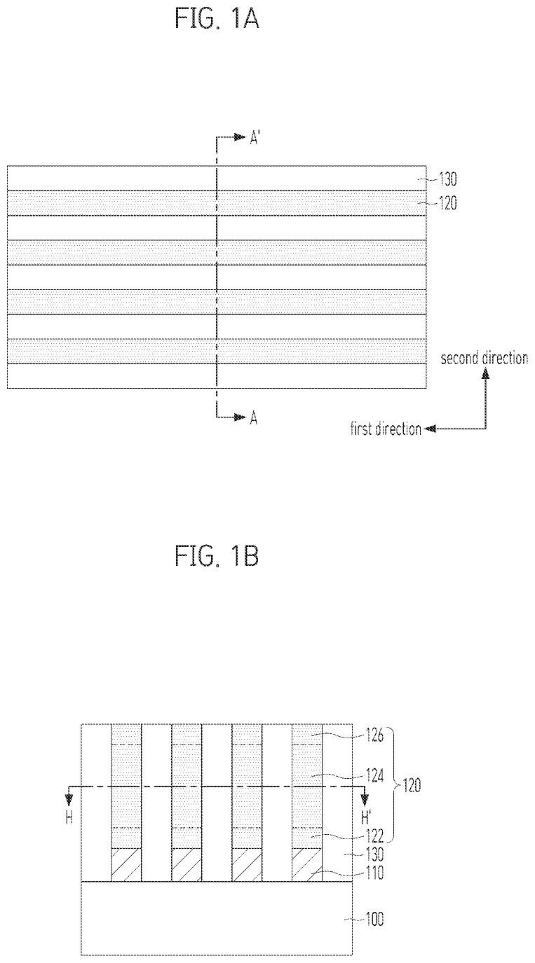

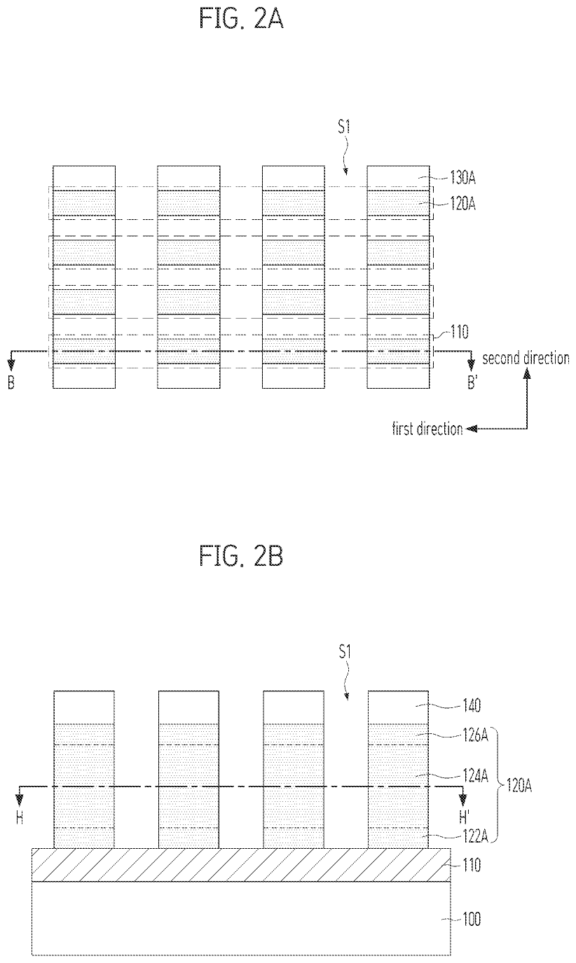

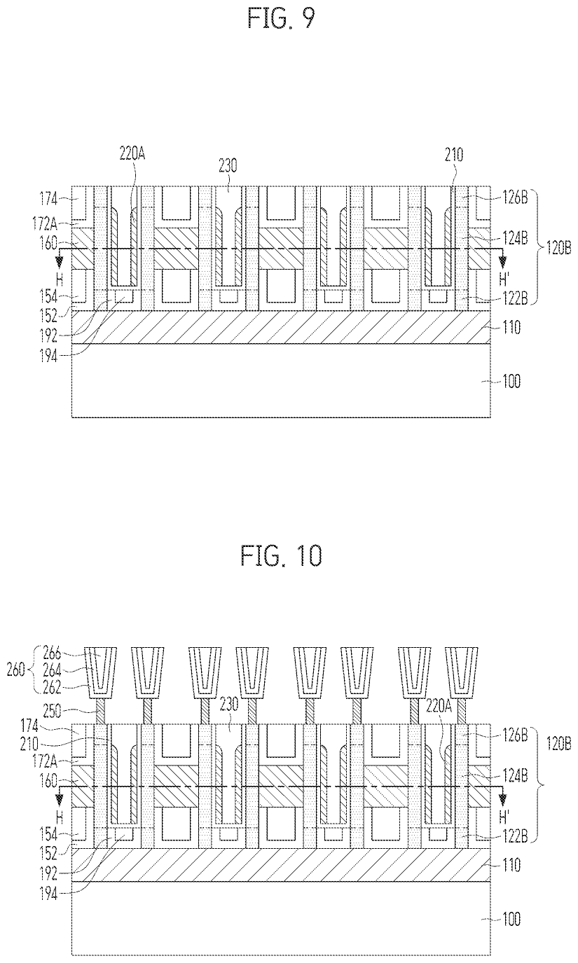

FIGS. 1A to 10 illustrate a semiconductor device and a method for fabricating the same in accordance with an embodiment of the present disclosure. FIGS. 1A, 2A, 3A, 4A, 5A, 6A, 7A, 8A, and 9A are plan views illustrating FIGS. 1B, 2B, 3B, 4B, 5B, 6B, 7B, 8B and 9B at the level of a line H-H′, respectively. FIG. 1B is a cross-sectional view taken along a line A-A′ shown in FIG. 1A. FIGS. 2B, 3B, 4B, 5B, 6B, 7B, and 8B and 9B are cross-sectional views taken along a line B-B′ shown in FIGS. 2A, 3A, 4A, 5A, 6A, 7A, 8A, and 9A, respectively. FIG. 10 is a cross-sectional view illustrating a process subsequent to FIG. 9B.

First, a method for fabricating a semiconductor device in accordance with this embodiment of the present disclosure will be described.

Referring to FIGS. 1A and 1B, a stacked structure including a conductive line 110 and a semiconductor layer 120 is formed over a substrate 100. A dielectric layer 130 may fill the space between a plurality of stacked structures 110, 120 spaced apart from each other along a first direction. Hence, stated differently, the dielectric layer 130 may fill the space between adjacent stacked structures 110 and 120.

The substrate 100 may be a semiconductor substrate. For example, the substrate may be made or include a semiconductor material, such as silicon. Also, the substrate 100 may include a lower structure (not shown), such as a driving circuit electrically connected to the conductive line 110 to drive the conductive line 110.

The conductive line 110 may extend in a first direction, and a plurality of the conductive lines 110 may be arranged spaced apart from each other in a second direction. The conductive line 110 may include diverse conductive materials, for example, metals, such as platinum (Pt), tungsten (W), aluminum (Al), copper (Cu), tantalum (Ta), titanium (Ti), ruthenium n (Ru) and molybdenum (Mo), compounds thereof, or alloys thereof. The conductive line 110 may correspond to a bit line that is coupled to a first end of a transistor, for example, a drain.

The semiconductor layer 120 may be disposed over the conductive line 110 and overlap with the conductive line 110 in terms of a plan view to have a line shape extending in the first direction. The semiconductor layers 120 may overlap with the conductive lines 110, respectively. For example, the semiconductor layer 120 may be patterned together with the conductive line 110 to have both sides aligned with both sides of the conductive line 110 in the second direction. The semiconductor layer 120 may include diverse semiconductor materials, such as silicon, silicon germanium, and the like. The semiconductor layer 120 may include a plurality of layers. Specifically, as illustrated in the embodiment of FIG. 1B, the semiconductor layer 120 may include a first source/drain region 122 disposed in the lower portion of the semiconductor layer 120, a second source/drain region 126 disposed in the upper portion (also referred to as a top portion) of the semiconductor layer 120, and a channel region 124 interposed between the first and second source/drain regions 122 and 126. For example, the source/drain region may refer to a source region or a drain region, and may be formed by doping a semiconductor material with an impurity. When the conductive line 110 corresponds to a bit line, the first source/drain region 122 may correspond to a drain region, and the second source/drain region 126 may correspond to a source region.

The dielectric layer 130 may include diverse dielectric materials, such as silicon oxide, silicon nitride, silicon oxynitride, or combinations thereof.

In an embodiment, the conductive line 110, the semiconductor layer 120, and the dielectric layer 130 may be formed in the following manner. First, a conductive material and a semiconductor material may be formed over the substrate 100. For example, the conductive material and the semiconductor material may be formed by a deposition method, such as Physical Vapor Deposition (PVD) or Chemical Vapor Deposition (CVD), or an epitaxial growth method. When a semiconductor material is deposited or grown, source/drain regions may be formed in the semiconductor material by doping an impurity in-situ. Subsequently, the stacked structure 110 and 120 of the conductive line 110 and the semiconductor layer 120 having a line shape may be formed by selectively etching the conductive material and the semiconductor material. Subsequently, the dielectric layer 130 may be formed by depositing a dielectric material that is thick enough to fill the empty space between the stacked structure 110 and 120, and performing a planarization process, such as Chemical Mechanical Polishing (CMP) or an etch-back process, until the top surface of the semiconductor layer 120 is exposed.

Referring to FIGS. 2A and 2B, initial semiconductor pillars 120A and initial insulating pillars 130A may be formed by forming a line-shaped hard mask pattern 140 that extends in the second direction over the semiconductor layer 120 and the dielectric layer 130, and etching the semiconductor layer 120 and the dielectric layer 130 by using the hard mask pattern 140 as an etch barrier.

The hard mask pattern 140 may include diverse dielectric materials, such as silicon oxide, silicon nitride, silicon oxynitride and the like, or may include amorphous carbon that may be easily removed.

The initial semiconductor pillars 120A may overlap with and may be coupled to the conductive line 110. The initial semiconductor pillars 120A may be arranged in the first and second directions. Also, the initial semiconductor pillars 120A and the initial insulating pillars 130A overlapping with one hard mask pattern 140 below the hard mask pattern 140 may be alternately arranged in the second direction, to form the initial line pattern 120A and 130A that extends in the second direction. A plurality of initial line patterns 120A and 130A may be arranged spaced apart from each other in the first direction. The etched first source/drain region, channel region, and second source/drain region are denoted by reference numerals 122A, 124A, and 126A, respectively. The space between the stacked structure that is formed by the initial line pattern 120A and 130A and the hard mask pattern 140 will be, hereinafter, referred to as a first space S1.

During the etching process, the conductive line 110 may be maintained as indicated by the dotted line in the plan view of FIG. 2A.

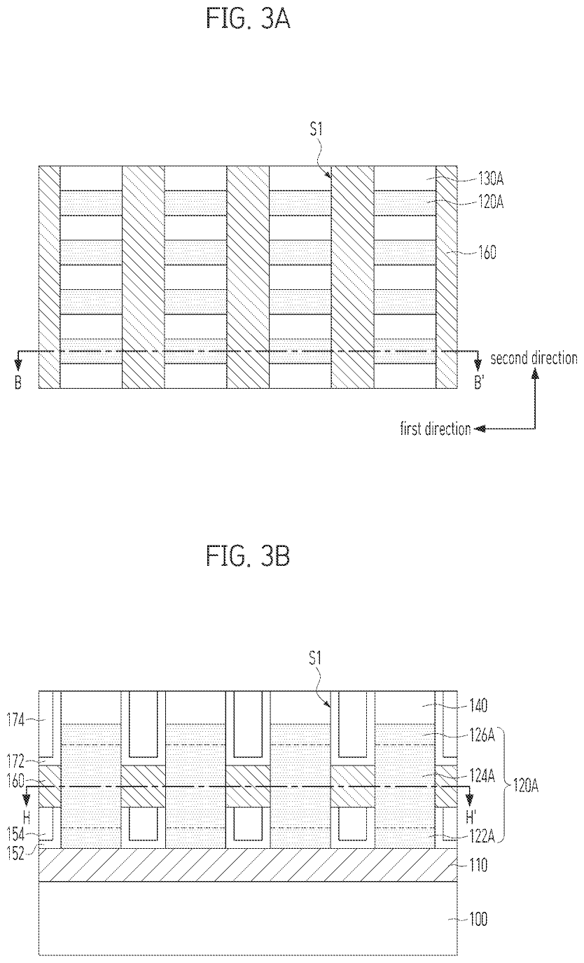

Referring to FIGS. 3A and 3B, a first insulating pattern 152 and 154 filling the lower portion of the first space S1, a back gate line 160 filling the middle portion of the first space S1 over the first insulating pattern 152 and 154, and a second insulating pattern 172 and 174 filling the upper portion of the first space S1 over the back gate line 160 may be formed.

The back gate line 160 may control a threshold voltage of a transistor by being electrically connected to the body of the transistor. According to an embodiment of the present disclosure, the back gate line 160 may directly contact both sides of the initial semiconductor pillar 120A and the initial insulating pillar 130A in the first direction while extending in the second direction. Also, according to an embodiment of the present disclosure, the bottom surface of the back gate line 160 may be disposed higher than the top surface of the first source/drain region 122A, and the top surface of the back gate line 160 may be disposed lower than the bottom surface of the second source/drain region 126A. As the distance between the bottom surface of the back gate line 160 and the top surface of the first source/drain region 122A and the distance between the top surface of the back gate line 160 and the bottom surface of the second source/drain region 126A increase, leakage current, such as Gate Induced Drain Leakage (GIDL), may be reduced. For example, the back gate line 160 may include polysilicon. However, the embodiments of the present disclosure are not limited thereto, and the back gate line 160 may include diverse semiconductor materials or conductive materials.

The first insulating pattern 152 and 154 may be interposed between the back gate line 160 and the conductive line 110 to insulate them from each other. The first insulating pattern 152 and 154 may have a line shape extending in the second direction. According to an embodiment of the present disclosure, the first insulating pattern 152 and 154 may include a first liner pattern 152 and a first buried pattern 154. The first liner pattern 152 may be conformally formed on the profile of the bottom surface and side of the lower portion of the first space S1, and the first buried pattern 154 may be formed to fill the remainder portion of the lower portion of the first space S1 in which the first liner pattern 152 is formed. The first liner pattern 152 may include silicon oxide, and the first buried pattern 154 may include silicon nitride. However, the embodiments of the present disclosure are not limited thereto, and each of the first liner pattern 152 and the first buried pattern 154 may be formed of diverse dielectric materials. Also, the first insulating pattern 152 and 154 may not be divided into the first liner pattern 152 and the first buried pattern 154 but may be formed as a single mass.

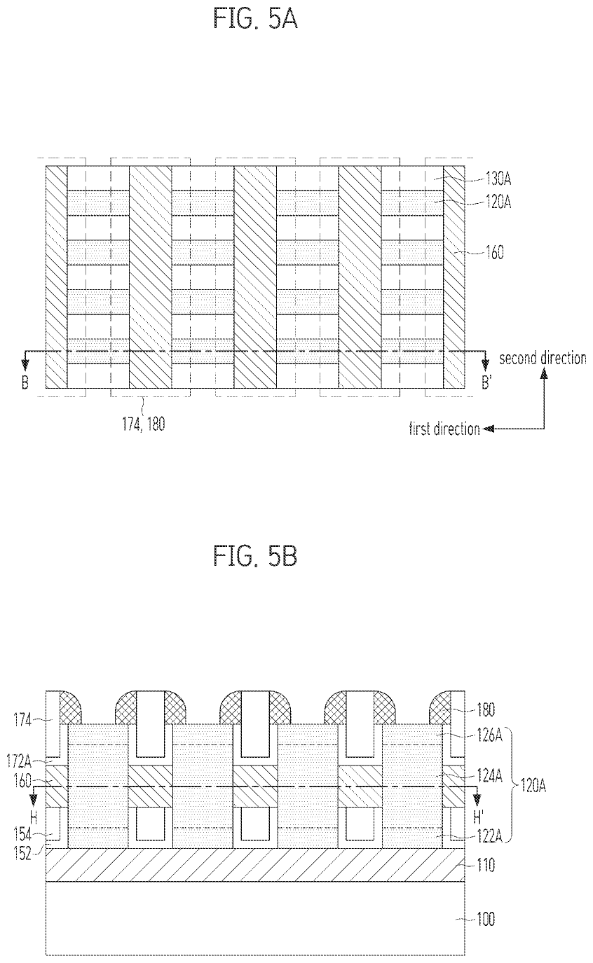

The second insulating pattern 172 and 174 may electrically insulate the back gate line 160 from the constituent elements (not shown) over the back gate line 160 by covering the back gate line 160. Also, the second insulating pattern 172 and 174 may serve to support spacers during the subsequent process of forming spacers (see reference numeral ‘180’ in FIGS. 5A and 5B). The second insulating pattern 172 and 174 may have a line shape extending in the second direction. According to an embodiment of the present disclosure, the second insulating pattern 172 and 174 may include a second liner pattern 172 and a second buried pattern 174. The second liner pattern 172 may be formed conformally on the profile of the bottom surface and side of the upper portion of the first space S1, and the second buried pattern 174 may be formed to fill the remainder portion of the upper portion of the first space S1 in which the second liner pattern 172 is formed. The second liner pattern 172 may include silicon oxide, and the second buried pattern 174 may include silicon nitride. However, the embodiments of the present disclosure are not limited thereto, and each of the second liner pattern 172 and the second buried pattern 174 may be formed of diverse dielectric materials. Also, the second insulating pattern 172 and 174 may not be divided into the second liner pattern 172 and the second buried pattern 174 but may be formed as a single mass.

The first insulating pattern 152 and 154, the back gate line 160, and the second insulating pattern 172 and 174 may be formed in the following manner. First, the first insulating pattern 152 and 154 may be formed by conformally depositing a first dielectric material for forming the first liner pattern 152 on the profile of the process result of FIGS. 2A and 2B, depositing a second dielectric material for forming the first buried pattern 154 over the deposited first dielectric material, recessing the second dielectric material by a method such as an etch-back process or the like so that the second dielectric material has a desired thickness, that is, the bottom surface of the back gate line 160 has a desired height, and removing the first dielectric material that is exposed by the recessed second dielectric material. When the first insulating pattern 152 and 154 form a single mass, the first insulating pattern 152 and 154 may be formed by depositing a dielectric material for forming the first insulating pattern 152 and 154 that covers the process result of FIGS. 2A and 2B, and recessing the deposited dielectric material to have a desired thickness. Subsequently, the back gate line 160 may be formed by depositing a material for forming the back gate line 160 to cover the process result in which the first insulating pattern 152 and 154 is formed, and recessing the deposited material so that the deposited material has a desired thickness, that is, the top surface of the back gate line 160 has a desired height. Subsequently, the second insulating pattern 172 and 174 may be formed by conformally depositing a first dielectric material for forming the second liner pattern 172 on the profile of the process result where the back gate line 160 is formed, then depositing a second dielectric material for forming the second buried pattern 174 over the deposited first dielectric material, and performing a planarization process to expose the hard mask pattern 140. When the second insulating pattern 172 and 174 forms a single mass, the second insulating pattern 172 and 174 may be formed by depositing a dielectric material for forming the second insulating pattern 172 and 174 that covers the process result where the back gate line 160 is formed and performing a planarization process to expose the hard mask pattern 140.

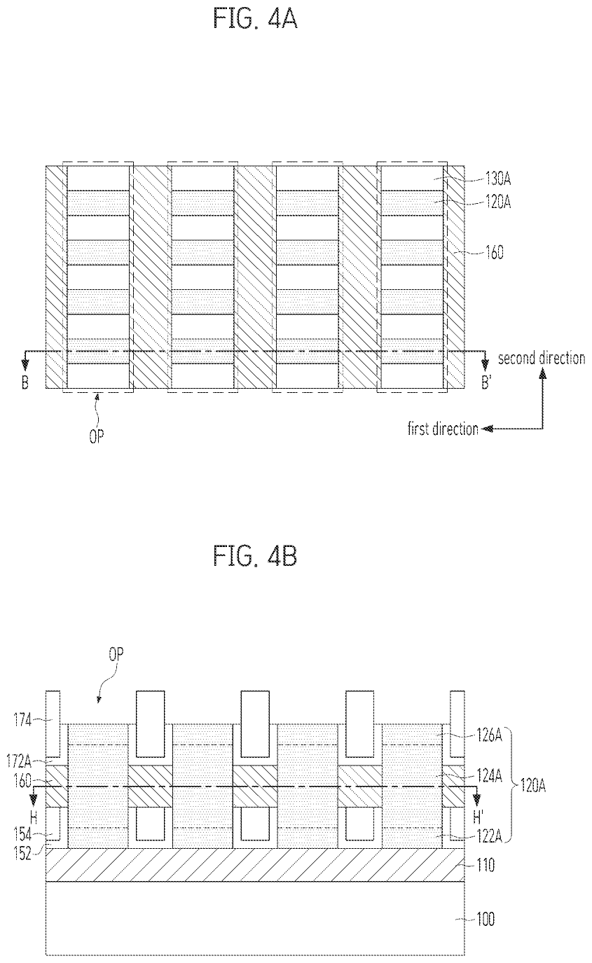

Referring to FIGS. 4A and 4B, the hard mask pattern 140 may be removed using, for example, a wet etching process or a dry etching process.

The space that is formed by removing the hard mask pattern 140 will be, hereinafter, referred to as an opening OP. The opening OP may expose the top surface of the initial line pattern 120A and 130A by having a line shape extending in the second direction and overlapping with the initial line pattern 120A and 130A. The shape of the opening OP is indicated by the dotted line in the plan view of FIG. 4A.

When the second liner pattern 172 and the hard mask pattern 140 include the same material, such as silicon oxide, a portion of the second liner pattern 172 may also be removed during the process of removing the hard mask pattern 140. The second liner pattern 172 a portion of which is removed is denoted by reference numeral ‘172A’. In this case, the top surface of the second liner pattern 172A and the bottom surface of the opening OP may be disposed at substantially the same height. However, the embodiments of the present disclosure are not limited to this, and the second insulating pattern 172 and 174 may be maintained when the hard mask pattern 140 is removed. As a result of this process, a portion of the second buried pattern 174 may protrude over the top surface of the initial semiconductor pillar 120A. When the second insulating pattern 172 and 174 is maintained while the hard mask pattern 140 is removed, a portion of the second insulating pattern 172 and 174 may protrude over the top surface of the initial semiconductor pillar 120A.

Referring to FIGS. 5A and 5B, spacers 180 may be formed on both sides of a protrusion portion of the second buried pattern 174 (or a protrusion portion of the second insulating pattern 172 and 174.)

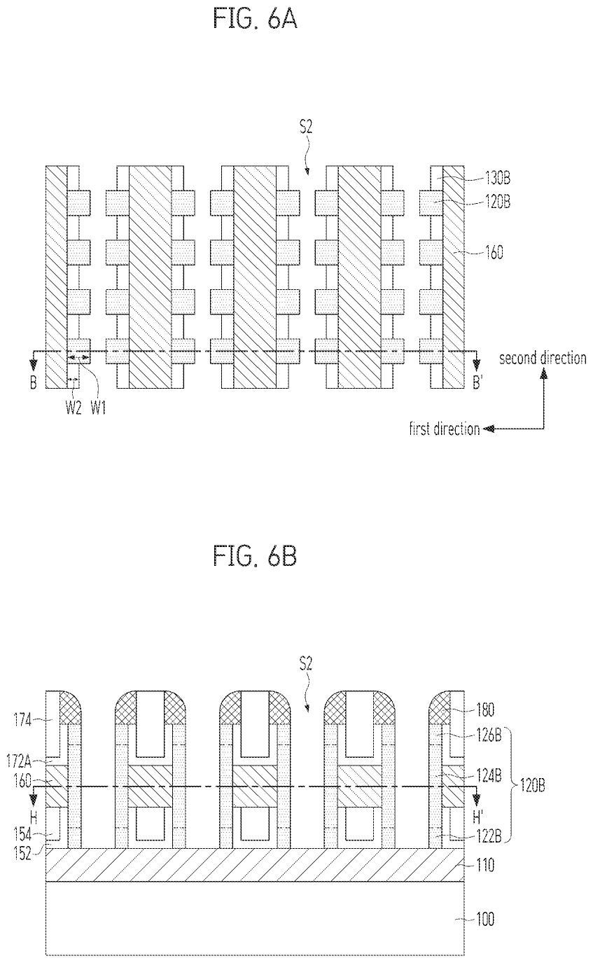

The spacers 180 may function as etch barriers during a subsequent etching process for forming semiconductor pillars and insulating pillars (see FIGS. 6A and 6B). The spacers 180 may have a line shape extending in the second direction. The spacers 180 may have a width increasing from top to bottom in terms of a cross-section. For example, in the first direction, the width of the bottom surface of the spacer 180 may be smaller than half the width of the initial semiconductor pillar 120A. Accordingly, one initial line pattern 120A and 130A may have a top surface that is partially covered by two spacers 180 overlapping with the initial line pattern 120A and 130A. When the two spacers 180 overlapping with one initial line pattern 120A and 130A are referred to as a first-side spacer 180 and a second-side spacer 180, respectively, a first portion corresponding to less than half from a first side of one initial line pattern 120A and 130A may overlap with the first-side spacer 180, and a second portion corresponding to less than half from a second side of one initial line pattern 120A and 130A may overlap with the second-side spacer 180. Moreover, the portion between the first portion and the second portion of the initial line pattern 120A and 130A may not overlap with the spacer 180. One second buried pattern 174 (or the second insulating pattern 172 and 174) and two spacers 180 on both sides of the second buried pattern 174 (see the dotted line portion in FIG. 5A) may cover one back gate line 160, and a portion of the two initial line patterns 120A and 130A disposed on both sides of the back gate line 160 in the first direction. These spacers 180 may include diverse dielectric materials, such as silicon oxide, silicon nitride, and silicon oxynitride, or may include amorphous carbon that may be easily removed.

The spacer 180 may be formed by conformally depositing a material over the process result of FIGS. 4A and 4B and then performing a blanket etching process. The blanket etching process may be performed to expose the top surface of the initial semiconductor pillar 120A.

Referring to FIGS. 6A and 6B, the semiconductor pillars 120B and the insulating pillars 130B may be formed by using the spacers 180 as an etch barrier and etching the initial semiconductor pillars 120A and the initial insulating pillars 130A. The semiconductor pillars 120B and the insulating pillars 130B may be alternately arranged in the second direction to form line patterns 120B and 130B extending in the second direction.

During the etching process, in the first direction, one initial semiconductor pillar 120A may be divided into two to form two semiconductor pillars 120B, and one initial insulating pillar 130A may be divided into two to form two insulating pillars 130B. In the first direction, the initial line pattern 120A and 130A may be divided into two to form two line patterns 120B and 130B. The space between the two divided line patterns 120B and 130B will be, hereinafter, referred to as a second space S2. The etched first source/drain region, channel region, and second source/drain region are denoted by reference numerals ‘122B’, ‘124B’, and ‘126B’, respectively.

This etching process may be performed through a dry etching method under the condition that the etch rate of the insulating pillars 130B is higher than that of the semiconductor pillars 120B. As a result, the width W1 of the semiconductor pillar 120B in the first direction may be greater than the width W2 of the insulating pillar 130B. In this case, since the semiconductor pillar 120B protrudes more toward the second space S2 than the insulating pillar 130B in the first direction, the second side facing the second space S2 among both sides of the semiconductor pillar 120B in the first direction, and the second side facing the second space S2 among both sides of the insulating pillar 130B in the first direction may form an unevenness. On the other hand, the first side contacting a side of the back gate line 160 among both sides of the semiconductor pillar 120B in the first direction and the first side contacting a side of the back gate line 160 among both sides of the insulating pillar 120B in the first direction may be disposed on a straight line extending in the second direction.

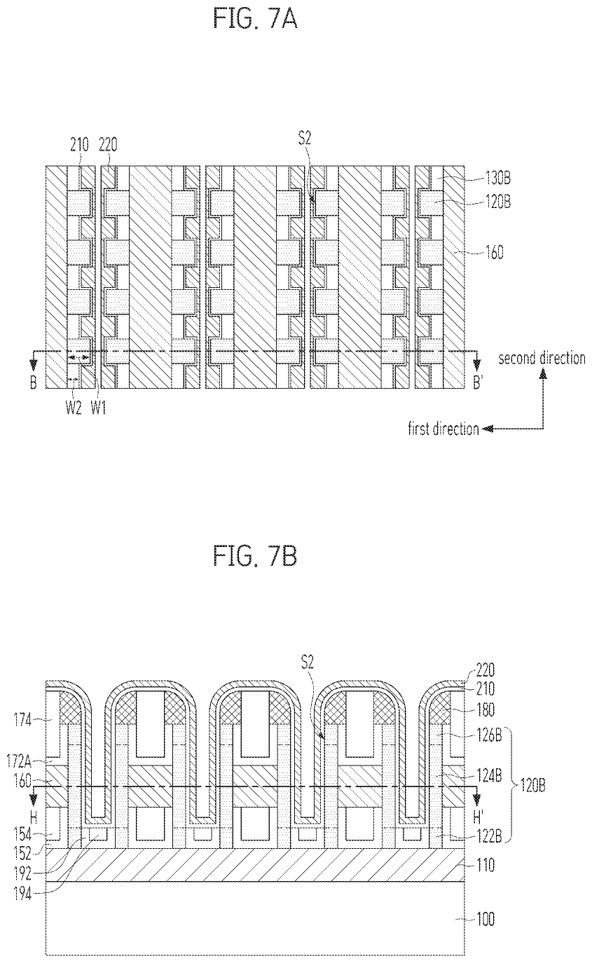

Referring to FIGS. 7A and 7B, after a third insulating pattern 192 and 194 filling the lower portion of the second space S2 is formed, a gate dielectric layer 210 and a front gate layer 220 may be formed conformally on the profile of the process result where the third insulating pattern 192 and 194 is formed.

The front gate layer 220 may correspond to a gate terminal of a transistor and/or a word line and may function to control the transistor to be turned on/off. The gate dielectric layer 210 may be interposed between the front gate layer 220 and the semiconductor pillar 120B to electrically insulate them from each other. The gate dielectric layer 210 and the front gate layer 220 may be formed to have a thin thickness that does not completely fill the second space S2 where the third insulating pattern 192 and 194 is formed. According to an embodiment of the present disclosure, the bottom surface of the front gate layer 220 may be disposed at the same or similar level as the top surface of the first source/drain region 122B and may be disposed lower than the bottom surface of the back gate line 160. The front gate layer 220 may include diverse conductive materials, for example, metals such as platinum (Pt), tungsten (W), aluminum (Al), copper (Cu), tantalum (Ta), titanium (Ti), ruthenium (Ru), molybdenum (Mo) and the like, compounds thereof, or alloys thereof. The gate dielectric layer 210 may include diverse dielectric materials, such as silicon oxide or a low-k material having a lower dielectric constant than silicon oxide.

The third insulating pattern 192 and 194 may be interposed between the front gate layer 220 and the conductive line 110 to insulate them from each other. The third insulating pattern 192 and 194 may have a line shape extending in the second direction. According to an embodiment of the present disclosure, the third insulating pattern 192 and 194 may include a third liner pattern 192 and a third buried pattern 194. The third liner pattern 192 may be formed conformally on the profile of the bottom surface and side of the lower portion of the second space S2, and the third buried pattern 194 may be formed to fill the remainder portion of the lower portion of the second space S2 in which the third liner pattern 192 is formed. The third liner pattern 192 may include silicon oxide, and the third buried pattern 194 may include silicon nitride. However, the embodiments of the present disclosure are not limited thereto, and each of the third liner pattern 192 and the third buried pattern 194 may be formed of diverse dielectric materials. Also, the third insulating pattern 192 and 194 may not be divided into the third liner pattern 192 and the third buried pattern 194 but may be formed as a single mass.

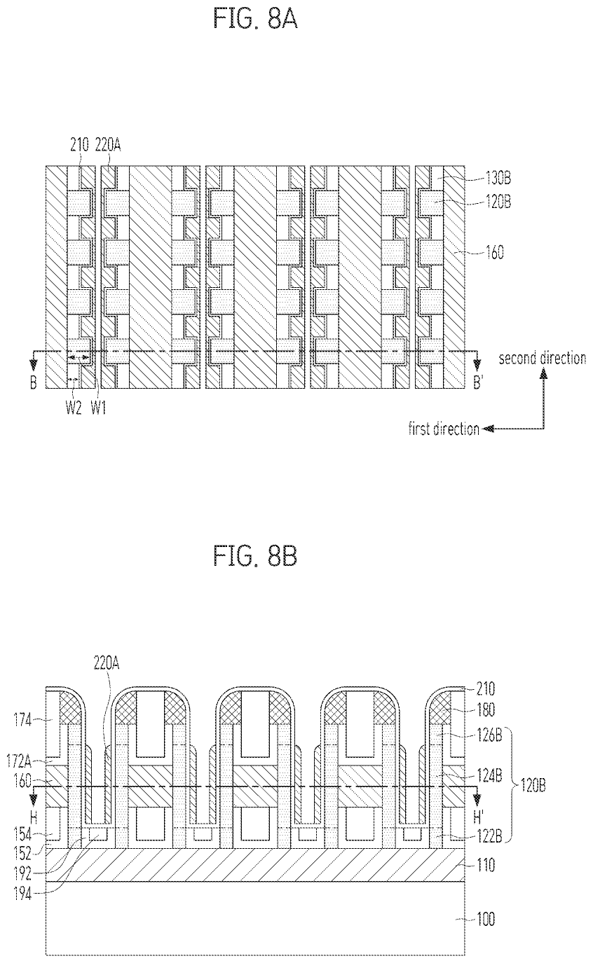

Referring to FIGS. 8A and 8B, a front gate line 220A may be formed on the second sides of the semiconductor pillar 120B and the insulating pillar 130B to extend in the second direction by etching the front gate layer 120. In the first direction, the front gate layer 120 may be divided into two parts in the second space S2 to form two front gate lines 220A.

The front gate lines 220A may be formed through a blanket etching process that is performed onto the front gate layer 220. For example, the blanket etching process may be performed to have a desired thickness of the front gate lines 220A while exposing at least the gate dielectric layer 210 on the bottom surface of the second space S2 to separate the front gate line 220A which is adjacent in the first direction, that is, the blanket etching process may be performed to dispose the top surface of the front gate lines 220A lower than the top surface of the semiconductor pillar 120B. According to an embodiment of the present disclosure, the top surface of the front gate line 220A may be disposed at the same or similar level as the bottom surface of the second source/drain region 126B and may be disposed over the top surface of the back gate line 160. Also, the bottom surface of the front gate line 220A may be disposed at the same or similar level as the top surface of the first source/drain region 122B, and may be disposed lower than the bottom surface of the back gate line 160. Accordingly, the front gate line 220A may have a greater thickness than the thickness of the back gate line 160.

Also, since the front gate line 220A is formed on the second side of the semiconductor pillar 120B and the second side of the insulating pillar 130B, which forms an unevenness in terms of a plane, it may surround the side of the protrusion portion of the semiconductor pillar 120B that protrudes more toward the front gate line 220A than the insulating pillar 130B. When the semiconductor pillar 120B has a square pillar shape and thus has third and fourth sides facing each other in the second direction while coupling the first and second sides along with the above-described first and second sides, the front gate line 220A may face the second side, a portion of the third side, and a portion of the fourth side of the semiconductor pillar 120B, while the back gate line 160 faces and contacts the first side of the semiconductor pillar 120B. In this case, the controllability of the front gate line 220A with respect to a channel of a transistor may be improved. Therefore, the operation characteristics of the transistor may be improved.

Accordingly, the transistor may be formed to include the semiconductor pillar 120B provided with the first source/drain region 122B, the channel region 124B, and the second source/drain region 126B, the back gate line 160 extending in the second direction while directly contacting the first side of the semiconductor pillar 120B, and the front gate line 220A extending in the second direction while surrounding a side of the protrusion portion of the semiconductor pillar 120B by interposing the gate dielectric layer 210, that is, the second side, a portion of the third side, and a portion of the fourth side of the semiconductor pillar 120B. When the second source/drain region 126B of the transistor corresponds to a source region, the second source/drain region 126B may be electrically connected to a memory pattern for storing data. This will be described by referring to the subsequent processes shown in FIGS. 9A to 10.

Referring to FIG. 9, after an inter-layer dielectric layer 230 that covers the process result of FIGS. 8A and 8B is formed, a planarization process may be performed to expose the top surface of the semiconductor pillar 120B. As a result of this process, the semiconductor pillar 120B, the second buried pattern 174, the gate dielectric layer 210, and the inter-layer dielectric layer 230 may form a flat top surface.

Referring to FIG. 10, a plurality of memory patterns 260, each memory pattern 260 being electrically connected to a corresponding semiconductor pillar of the plurality of the semiconductor pillars 120B, particularly, to the respective second source/drain region 126B, through a corresponding contact plug of the plurality of contact plugs 250 may be formed over the process result of FIG. 9.

The contact plugs 250 may include diverse conductive materials, for example, metals such as platinum (Pt), tungsten (W), aluminum (Al), copper (Cu), tantalum (Ta), titanium (Ti), ruthenium (Ru), molybdenum (Mo) and the like, compounds thereof, or alloys thereof. Each of the contact plugs 250 may correspond to a storage node contact that is electrically connected to a second end of the transistor, for example, a source.

The memory patterns 260 may refer to constituent elements that may store data in diverse ways. According to an embodiment of the present disclosure, the memory patterns 260 may each include a capacitor with a dielectric layer 264 interposed between two electrodes 262 and 266. The capacitor may be formed by forming another inter-layer dielectric layer (not shown) over the process result of FIG. 9, forming a hole that exposes the top surface of the semiconductor pillar 120B by selectively etching the inter-layer dielectric layer, forming a first electrode 262 by depositing a conductive material on the profile of the inner wall of the hole, forming a dielectric layer 264 on the profile of the surface of the first electrode 262, and forming a second electrode 266 by filling the remaining space of the hole where the first electrode 262 and the dielectric layer 264 are formed with a conductive material. In this case, a cylindrical capacitor may be formed.

However, the embodiments of the present disclosure are not limited to forming cylindrical capacitors only, and the memory pattern 260 may include capacitors of diverse shapes. Also, the memory pattern 260 may include diverse elements capable of storing data other than the capacitor. For example, the memory pattern 260 may include a variable resistance element that may store different data by switching between different resistance states.

The semiconductor device in accordance with the embodiment of the present disclosure may be fabricated by the above-described method for fabricating a semiconductor device.

The semiconductor device in accordance with the embodiment of the present disclosure may include a substrate 100, a conductive line 110 disposed over the substrate 100 and extending in the first direction, a plurality of semiconductor pillars 120B arranged in the second direction while being electrically connected to the conductive line 110 over the conductive line 110, a plurality of insulating pillars 130B arranged alternately with the semiconductor pillars 120B in the second direction, a back gate line 160 formed on the first sides of the semiconductor pillars 120B and the insulating pillars 130B in the first direction and extending in the second direction, a front gate line 220A formed on the second sides of the semiconductor pillars 120B and the insulating pillars 130B in the first direction and extending in the second direction, and a memory pattern 260 electrically connected to the semiconductor pillar 120B through a contact plug 250 over the semiconductor pillar 120B.

Two line patterns 120B and 130B including a plurality of semiconductor pillars 120B and a plurality of insulating pillars 130B that are alternately arranged in the second direction may be disposed on both sides of one back gate line 160. For example, the first sides of the two line patterns 120B and 130B may contact both sides of the back gate line 160, respectively. Two front gate lines 220A may be formed on the second sides of the two line patterns 120B and 130B, respectively. Accordingly, in the first direction, the line patterns 120B and 130B and the front gate line 220A disposed on the first side of the back gate line 160, and the line patterns 120B and 130B and the front gate line 220A disposed on the second side of the back gate line 160 may have a symmetrical structure. When a structure formed by one back gate line 160, the line patterns 120B and 130B and the front gate line 220A on the first side of the back gate line 160, and the line patterns 120B and 130B and the front gate line 220A on the second side of the back gate line 160 is referred to as a first structure, a plurality of the first structures may be repeatedly arranged in the first direction.

For example, in the first direction, the semiconductor pillar 120B may have a protrusion portion that protrudes more toward the front gate line 220A than the insulating pillar 130B, and the front gate line 220A may surround the side of the protrusion portion of the semiconductor pillar 120B.

Since the constituent elements of the semiconductor device in accordance with the embodiment of the present disclosure have already been described in detail in the process of describing the method for fabricating a semiconductor device, a description of them will be omitted herein.

According to the semiconductor device and the method for fabricating a semiconductor device described above, the following effects may be obtained.

First, since the back gate line 160 is shared between the two semiconductor pillars 120B as the back gate line 160 and the front gate line 220A are alternately disposed and the semiconductor pillars 120B with a narrower width than the limitation of a mask process may be formed as the semiconductor pillars 120B are formed by using the spacer 180, it is possible to form a large number of transistors in a small area. Namely, the integration degree of a semiconductor device may be improved.

Also, since the front gate line 220A surrounds the side of the protrusion portion of the semiconductor pillar 120B, the controllability of the front gate line 220A with respect to the channel of the transistor may be improved. As a result, the operation characteristics of the transistor may be improved.

Also, the back gate line 160 may directly contact the semiconductor pillar 120B to suppress the floating body effect, and the distance to the first and second source/drain regions 122B and 126B may be increased due to a decrease in the thickness of the back gate line 160, which may decrease the leakage current. In this way, it is possible to reduce and/or eliminate the factors that may deteriorate the characteristics of the transistor.

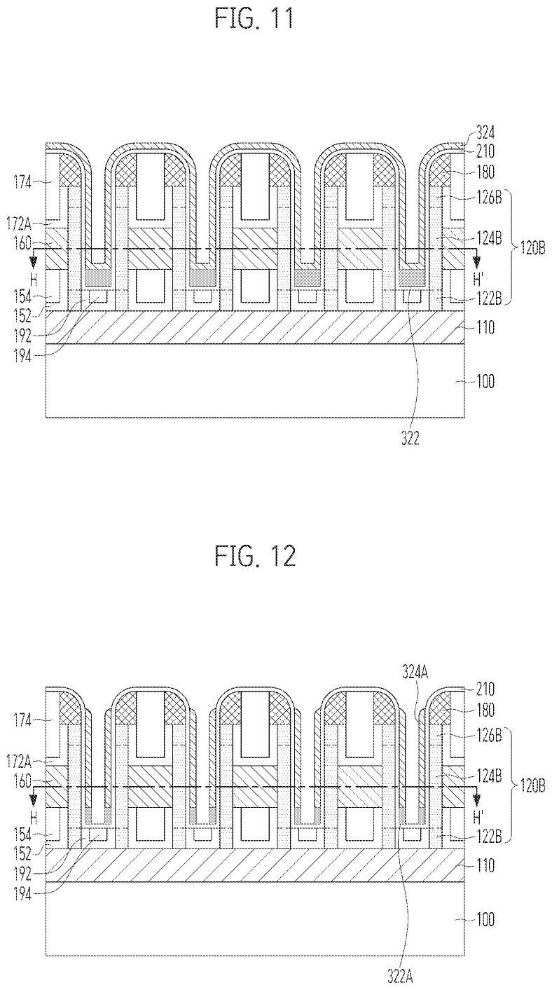

Furthermore, the front gate line may have a multi-layer structure containing different materials to improve the characteristics of the transistor. For example, when a portion of the front gate line close to the source/drain region has a low work function, the electric field may be decreased, thereby reducing the leakage current, such as Gate Induced Drain Leakage (GIDL). A method for realizing the front gate line will be described below by referring to FIGS. 11 to 14.

FIGS. 11 to 14 are cross-sectional views illustrating a semiconductor device and a method for fabricating the same in accordance with another embodiment of the present disclosure. The same reference numerals may be given to substantially the same constituent elements also appearing in the above-described embodiment, and the detailed description of them may be omitted.

Referring to FIG. 11, after the same processes as those described in FIGS. 1A to 6B are performed to obtain the process result of FIG. 6B, the third insulating pattern 192 and 194 may be formed to fill the lower portion of the second space S2, and the gate dielectric layer 210 may be formed conformally on the profile of the process result where the third insulating pattern 192 and 194 is formed.

Subsequently, a first front gate layer 322 may be formed over the gate dielectric layer 210 to fill the lower portion of a third space defined by the side and bottom surfaces of the gate dielectric layer 210. The first front gate layer 322 may be formed by depositing a material for forming the first front gate layer 322 over the gate dielectric layer 210 to a thickness that sufficiently fills the third space, and recessing the material to have a desired thickness. The first front gate layer 322 may include a material having a first work function, such as polysilicon. The top surface of the first front gate layer 322 may be disposed at the same or similar height as the bottom surface of the back gate line 160, but the embodiments of the present disclosure are not limited thereto, and the height of the top surface of the first front gate layer 322 may be modified diversely.

Subsequently, a second front gate layer 324 may be formed conformally on the profile of the process result where the first front gate layer 322 is formed. The second front gate layer 324 may be formed to have a thin thickness that does not completely fill the third space. The second front gate layer 324 may include a material having a second work function which is greater than the first work function, such as a metal, a metal compound, or an alloy.

Referring to FIG. 12, a first front gate line 322A and a second initial front gate line 324A may be formed on the second sides of the semiconductor pillar 120B and the insulating pillar by etching the first and second front gate layers 322 and 324 to extend in the second direction. In the first direction, the first front gate layer 322 and the second front gate layer 324 may be divided into two parts in the third space to form two first front gate lines 322A and two second initial front gate lines 324A.

The second initial front gate line 324A may be formed through a blanket etching process that is performed onto the second front gate layer 324. For example, the blanket etching process may be performed such that the top surface of the first front gate layer 322 is exposed and the top surface of the second initial front gate line 324A is disposed lower than at least the top surface of the spacer 180. The first front gate line 322A may be formed by etching and removing a portion of the first front gate layer 322 that is exposed by the second initial front gate line 324A. As a result, a stacked structure of the first front gate line 322A and the second initial front gate line 324A may be formed.

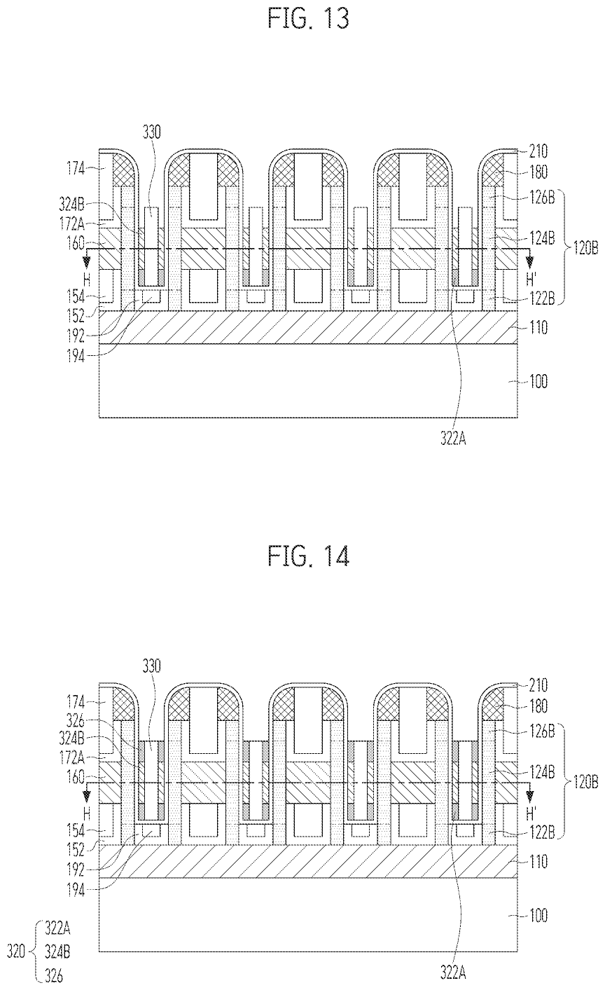

Referring to FIG. 13, an additional insulating pattern 330 may be formed to fill the space between the stacked structure of the first front gate line 322A and the second initial front gate line 324A. The additional insulating pattern 330 may include diverse dielectric materials, and may be formed by depositing a dielectric material that covers the process result of FIG. 12 and recessing the additional insulating pattern 330 to have a desired thickness. The top surface of the additional insulating pattern 330 may be disposed lower than the top surface of the second initial front gate line 324A, and may be disposed at the same or higher level than the top surface of a front gate line (see reference numeral ‘320’ shown in FIG. 14), which will be described in a subsequent process.

Subsequently, the second initial front gate line 324A may be recessed to form a second front gate line 324B with a decreased thickness.

Referring to FIG. 14, a third front gate line 326 may be formed to fill the space formed by the recess of the second initial front gate line 324A, that is, the space that is defined by the side of the gate dielectric layer 210, the top surface of the second front gate line 324B, and the side of the additional insulating pattern 330.

The third front gate line 326 may be formed by depositing a material over the process result of FIG. 13 and recessing the material to have a desired thickness. The third front gate layer 326 may include a material having a first work function, such as polysilicon. The top surface of the third front gate layer 326 may be disposed at the same or similar height as the top surface of the back gate line 160, but the embodiments of the present disclosure are not limited thereto, and the height of the top surface of the third front gate layer 326 may be modified diversely.

Through the process described above, the front gate line 320 in which the first, second, and third front gate lines 322A, 324B, and 326 are stacked may be formed.

The first front gate line 322A and the third front gate line 326 may have a smaller work function than the second front gate line 324B. Also, the first front gate line 322A may be disposed closer to the first source/drain region 122B than the second front gate line 324B, and the second front gate line 326 may be disposed closer to the second source/drain region 126B than the second front gate line 324B. Therefore, as described above, it may be possible to reduce the electric field of the transistor and to reduce the leakage current caused by the reduced electric field.

Since the subsequent process may be substantially the same as what is described in FIGS. 9 and 10, a detailed description thereof will be omitted.

The embodiments described above may be applied to all semiconductor devices including NMOS transistors, PMOS transistors, or CMOS transistors and methods for fabricating the semiconductor device. For example, they may be also applied to non-volatile memories, such as a flash memory, a resistive random-access memory (RRAM), a phase-change random access memory (PRAM), a magneto-resistive random-access memory (MRAM) and the like, volatile memories, such as a dynamic random access memory (DRAM), a static random access memory (SRAM) and the like, non-memories, such as a logic circuit, and diverse semiconductor devices, such as a CMOS image sensor (CIS).

According to an embodiment of the present disclosure, a semiconductor device including a transistor capable of increasing an integration degree and improving operation characteristics, and a method for fabricating the semiconductor device may be provided.

While the embodiments of the present disclosure have been described with respect to specific embodiments, it will be apparent to those skilled in the art that various changes and modifications may be made without departing from the spirit and scope of the invention as defined in the following claims. Furthermore, the embodiments may be combined to form additional embodiments.

What is claimed is:

1. A semiconductor device comprising:
a plurality of semiconductor pillars having first and second sides facing each other in a first direction, and arranged in a second direction intersecting with the first direction;
a plurality of insulating pillars having first and second sides facing each other in the first direction, and arranged alternately with the semiconductor pillars in the second direction;
a back gate line formed on the first sides of the semiconductor pillars and the first sides of the insulating pillars, and extending in the second direction; and
a front gate line formed on the second sides of the semiconductor pillars and the second sides of the insulating pillars, and extending in the second direction,
wherein the semiconductor pillars respectively include protrusion portions that protrude more than the insulating pillars toward the front gate line in the first direction, and
wherein the front gate line surrounds a side of the protrusion portion.

2. The semiconductor device of claim 1, wherein the first sides of the semiconductor pillars and the first sides of the insulating pillars are disposed on a straight line extending in the second direction.

3. The semiconductor device of claim 1, wherein a width of the semiconductor pillar in the first direction is greater than a width of the insulating pillar.

4. The semiconductor device of claim 1, wherein the back gate line directly contacts the semiconductor pillars.

5. The semiconductor device of claim 1, further comprising:
a gate dielectric layer interposed between the front gate line and the semiconductor pillars.

6. The semiconductor device of claim 1, wherein a thickness of the back gate line is smaller than a thickness of the front gate line.

7. The semiconductor device of claim 1, wherein the semiconductor pillar includes a first source/drain region disposed in a lower portion of the semiconductor pillar, a second source/drain region disposed in an upper portion of the semiconductor pillar, and a channel region interposed between the first source/drain region and the second source/drain region,
wherein a bottom surface of the back gate line is disposed higher than a top surface of the first source/drain region, and
a top surface of the back gate line is disposed lower than a bottom surface of the second source/drain region.

8. The semiconductor device of claim 7, wherein a bottom surface of the front gate line is disposed lower than the bottom surface of the back gate line, and
a top surface of the front gate line is disposed higher than the top surface of the back gate line.

9. The semiconductor device of claim 1, wherein the front gate line includes a first front gate line, a second front gate line over the first front gate line, and a third front gate line over the second front gate line, and
wherein work functions of the first front gate line and the third front gate line are smaller than a work function of the second front gate line.

10. The semiconductor device of claim 1, further comprising:
a conductive line electrically connected to the semiconductor pillar below the semiconductor pillar, and extending in the first direction; and
a memory pattern electrically connected to the semiconductor pillar over the semiconductor pillar.

11. A semiconductor device comprising:
a back gate line having both sides facing each other in a first direction and extending in a second direction intersecting with the first direction;
two line patterns respectively formed on both sides of the back gate line and respectively having first sides facing the back gate line, each of the two line patterns including a plurality of semiconductor pillars and a plurality of insulating pillars that are alternately arranged in the second direction; and
two front gate lines respectively formed on two second sides facing the first sides of the two line patterns in the first direction.

12. The semiconductor device of claim 11, wherein the back gate line, the two line patterns, and the two front gate lines form a first structure, and
a plurality of the first structures are repeatedly arranged in the first direction.

13. The semiconductor device of claim 11, wherein the two line patterns are symmetrical to each other with the back gate line interposed therebetween, and
wherein the two front gate lines are symmetrical to each other with the back gate line interposed therebetween.

14. The semiconductor device of claim 11, wherein the semiconductor pillar includes a protrusion portion that protrudes more than the insulating pillar toward the front gate line in the first direction, and
wherein the front gate line surrounds a side of the protrusion portion.

15. The semiconductor device of claim 11, wherein the first sides of the line patterns are disposed on a straight line extending in the second direction, and
the second sides of the line patterns have an uneven shape.
